(19) United States
(12) Patent Application Publication
(10) Pub. No.: US 2013/0069217 A1
(43) Pub. Date: Mar. 21, 2013

(54) SEMICONDUCTOR DEVICE AND ELECTRODE TERMINAL

(71) Applicant: Junichi NAKAO, Hyogo-ken (JP)

(72) Inventor: Junichi NAKAO, Hyogo-ken (JP)

(73) Assignee: Kabushiki Kaisha Toshiba, Tokyo (JP)

(21) Appl. No.: 13/421,795

(22) Filed: Mar. 15, 2012

(30) Foreign Application Priority Data
Sep. 21, 2011 (JP) 2011-205705

(51) Int. Cl. H01L 23/538; H01B 5/02

(52) U.S. Cl. 257/696; 174/135; 257/E23.175

(57) ABSTRACT

According to one embodiment, a semiconductor device includes a substrate, a semiconductor chip mounted on the substrate, an electrode electrically connected to the semiconductor chip, an electrode terminal having a first terminal at one end portion and a second terminal at the other end portion, and a case covering the substrate, the electrode, the first terminal and the second terminal, wherein the first terminal and the second terminal are bended to direct to a center portion and to be opposed each other in the case, and the first terminal and the second terminal are close to each other to be soldered with the electrode.

### CROSS REFERENCE TO RELATED APPLICATION

This application is based upon and claims the benefit of priority from prior Japanese Patent Application No. 2011-205705, filed on Sep. 21, 2011, the entire contents of which are incorporated herein by reference.

### FIELD

Exemplary embodiments described herein generally relate to a semiconductor device and an electrode terminal.

### BACKGROUND

A power module represented by IGBT (Insulated Gate Bipolar Transistor) has been used as a switching device to transform electric power.

In a semiconductor device implemented a power module, a semiconductor chip such as an IGBT or the like mounted on a circuit board is electrically connected to an electrode provided on the circuit board. An electrode terminal connected to an outer source is connected the electrode by solder technique.

The electrode terminal has a bended shape at a surface to be soldered to widen an area of a soldered portion.

Consequently, when thermal stress is generated by a thermal fatigue test (TFT) or the like, large thermal stress is repeatedly applied to the solder junction portion of the bend portion.

As a result, there arise a problem that solder crack is generated at the bend portion of the electrode terminal to decrease reliability of the semiconductor device.

### BRIEF DESCRIPTION OF THE DRAWINGS

FIG. 1 is a schematic cross-sectional view showing a constitution of a semiconductor device according to an embodiment;

FIG. 2 is an enlarged cross-sectional view showing a solder junction portion of an electrode terminal as shown in FIG. 1 according to the embodiment;

FIG. 3 is an enlarged cross-sectional view showing a solder junction portion of an electrode terminal according to a comparative example;

FIG. 4 is a schematic cross-sectional view showing distorted state of the semiconductor device due to tensile stress according to the embodiment;

FIG. 5 is a schematic cross-sectional view showing a state when tensile stress is generated and applied to the solder junction portion of the electrode terminal according to the comparative example;

FIG. 6 is a schematic cross-sectional view showing a state when tensile stress is generated and applied to the solder junction portion of the electrode terminal according to the embodiment;

FIG. 7 is an exemplary table showing TFT test data according to the embodiment;

FIG. 8 is a schematic plane view showing a constitution of a semiconductor device in which a plurality of chips have common electrodes according to the embodiment; and

FIGS. 9A, 9B are an exemplary schematic view showing an electrode terminal with two pairs of terminals.

### DETAILED DESCRIPTION

According to one embodiment, a semiconductor device includes a substrate, a semiconductor chip mounted on the substrate, an electrode electrically connected to the semiconductor chip, an electrode terminal having a first terminal at one end portion and a second terminal at the other end portion, and a case covering the substrate, the electrode, the first terminal and the second terminal, wherein the first terminal and the second terminal are bended to direct to a center portion and to be opposed each other in the case, and the first terminal and the second terminal are close to each other to be soldered with the electrode.

According to another embodiment, an electrode terminal includes a plane portion formed as a planer board, and a first terminal portion and a second terminal portion being bended in nearly orthogonal direction from both edges of the plane portion and further being bended back to be directed to a center portion of the electrode terminal such that the first terminal portion and the second terminal portion being opposed to each other, bend portions of the first terminal portion and the second terminal portion being back to back each other and further being bended to lead to surfaces to be soldered with the electrode, each of leading edges of the bend portions being set to be outward-directed.

Embodiment will be described below in detail with reference to the attached drawings mentioned above. Throughout the attached drawings, similar or same reference numerals show similar, equivalent or same components. Therefore, the descriptions of the portions will not be repeated.

### Embodiment

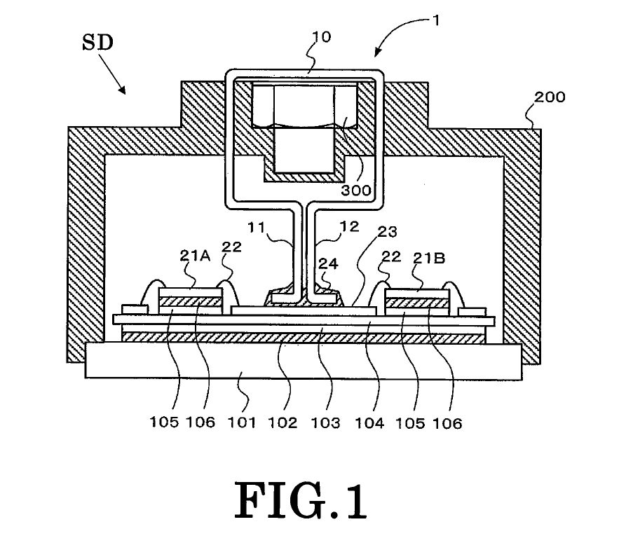

FIG. 1 is a schematic cross-sectional view showing a constitution of a semiconductor device according to an embodiment. A semiconductor device SD is a power module on which a semiconductor chip of a power device such as an IGBT or the like, for example, is provided.

The semiconductor device SD includes a metal base 101, a solder 102, a lower electrode 103, a substrate 104, upper electrodes 105, solders 106, semiconductor chips 21A, 21B bonding wires 22 and an electrode 23. The metal base 101 acts as a heat dissipation substrate. In the substrate 104, the lower electrode 103 is provided on a lower surface of the substrate 104. The lower electrode 103 is connected to the metal base 101 with the solder 102. Each of the upper electrodes 105 is provided on an upper surface of the substrate 104. Each of the semiconductor chips 21A, 21B are connected to each of the upper electrodes 105 with each of the bonding wires, respectively.

The substrate 104 is covered with a case 200 which is adhered to the metal base 101 with an adhesive material. Generally, an electrode terminal 1 to connect to the electrode 23 is provided at an upper surface portion of the case 200 in a power module and extends in a direction towards an inner portion of the case 200. In a case of IGBT, the electrode terminal 1 is used as a collector electrode terminal or an emitter electrode terminal.

In the electrode terminal 1, a plane portion 10 formed as a flat plane board is exposed outside the case 200. Further, both ends of the plane portion 10 is nearly perpendicularly bended to extend in a direction toward inside the case 200 as a terminal 11 and a terminal 12 which are denoted by a first terminal portion and a second terminal portion, respectively. Further, nut 300 is installed in the case 200 beneath the plane portion of the electrode terminal 1.

Both the terminal 11 and the terminal 12 extended to inside the case 200 are bended back to a center portion of the case 200 to close each other and are soldered to the electrode 23 with a solder 24.

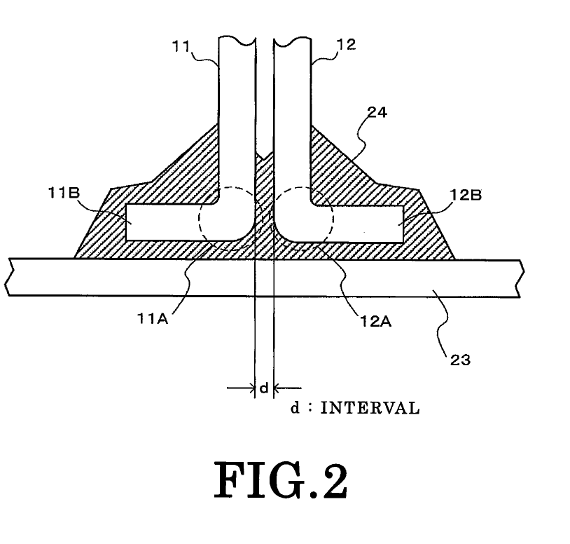

FIG. 2 is an enlarged cross-sectional view showing a solder junction portion of the electrode terminal 1 as shown in FIG. 1 according to the embodiment.

In the terminal 11 and the terminal 12, bend portions 11A, 12A which are bended to lead to surfaces to be soldered, respectively, are formed back to back each other and leading edges 11B, 12B are set to be outward-directed each other.

Further, an interval d is set between the bend portion 11A of the terminal 11 and the bend portion 12A of the terminal 12. The interval d is set approximately 1 mm in maximum.

The solder 24 is pulled up in a portion between the bend portion 11A of the terminal 11 and the bend portion 12A of the terminal 12 by setting the interval d to increase a thickness of the solder around the bend portions 11A, 12A.

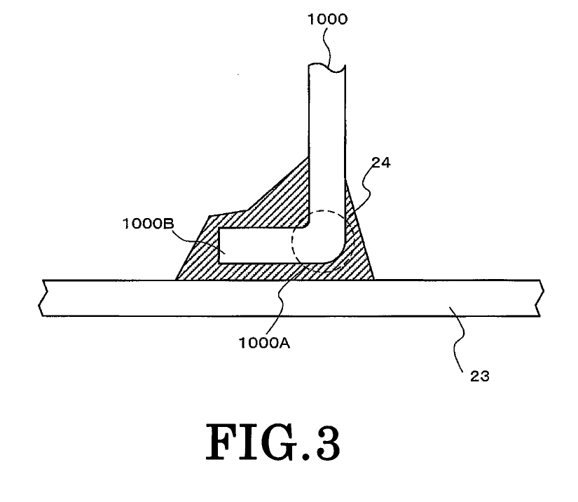

FIG. 3 is an enlarged cross-sectional view showing a solder junction portion in which one electrode terminal 100 is soldered to an electrode 23 according to a comparative example. In this case, a thickness of a solder around a bending portion 1000A is thinner.

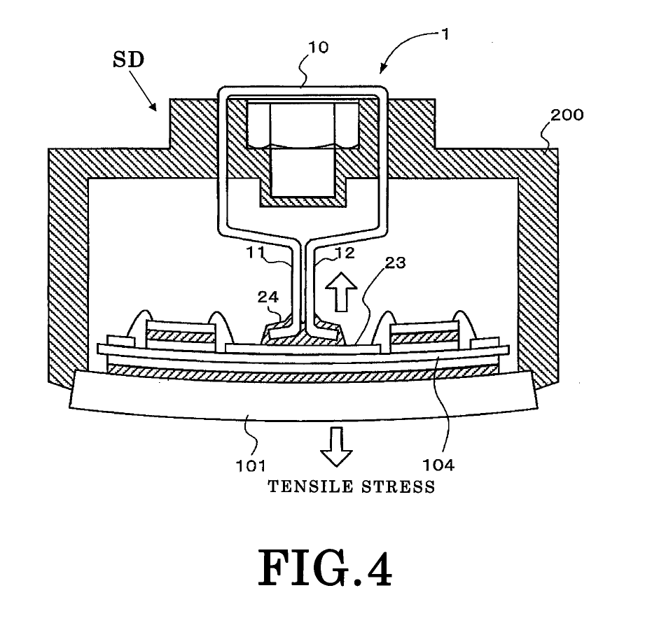

FIG. 4 is a schematic cross-sectional view showing distorted state of the semiconductor device SD due to tensile stress according to the embodiment. When the metal base is composed of copper (Cu) the substrate is set to be a ceramic substrate which is composed of nitride aluminum (AlN), for example, the metal base 101 is expanded outside to be distorted due to a difference between thermal expansion coefficient of Cu, 17×10⁻⁶/K, and thermal expansion coefficient of the ceramic substrate, 4.6×10⁻⁶/K, as shown in FIG. 4.

When such a distortion is generated, terminals 11, 12 are extended upper and lower directions as the terminals 11, 12 are fixed on the case 200. As a result, large tensile stress as shown by an arrow in FIG. 4 is generated at a solder junction portion of the electrode 23 on which the terminals 11, 12 are bonded each other.

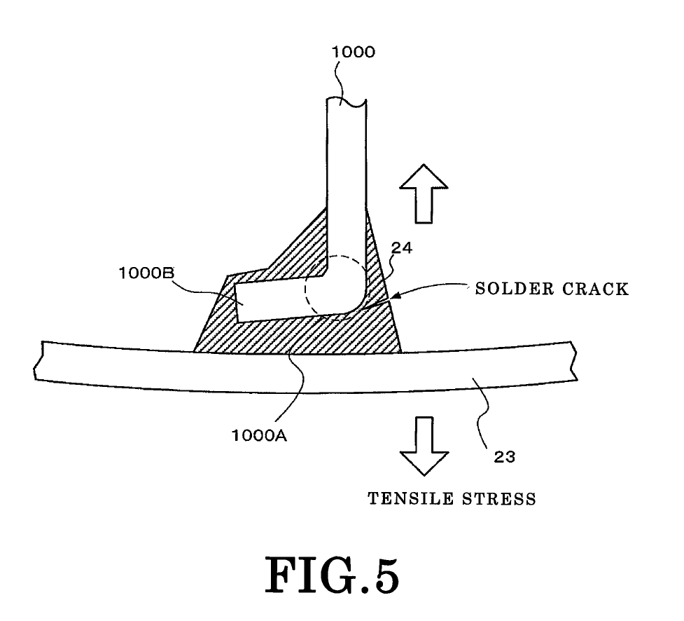

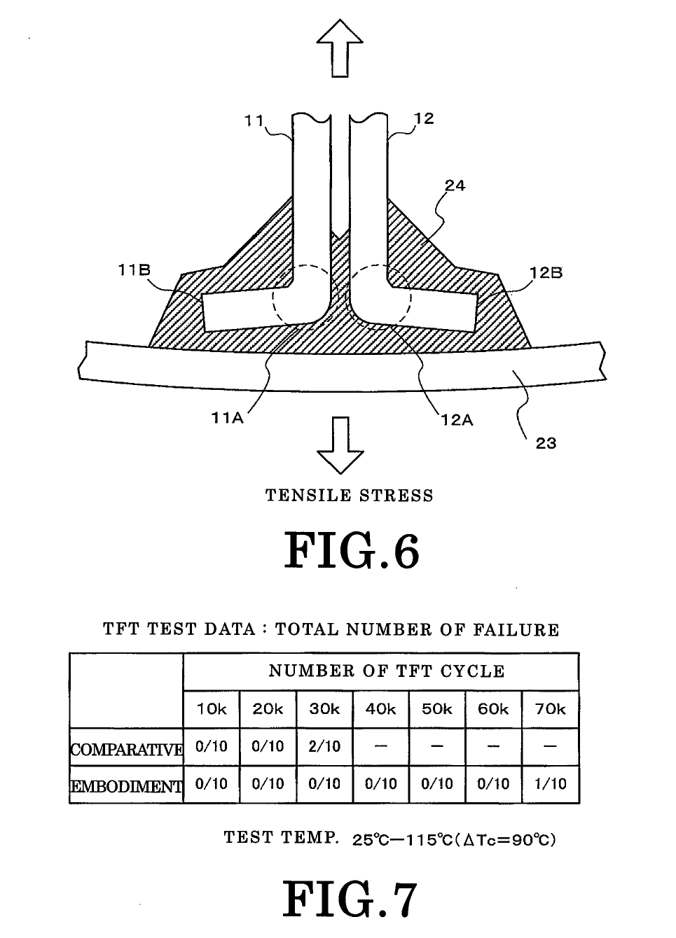

When such tensile stress is generated, tensile stress is applied to the solder 24 around the bend portion 1000A of the electrode terminal 1000 as shown in FIG. 5 in a case of the comparative example as shown in FIG. 3. In such a manner, when tensile stress is repeatedly applied to the solder 24 by a TFT test or the like, solder crack is generated in the solder 24 around the bend portion 1000A as shown in FIG. 5.

On the other hand, the solder 24 around the bend portions 11A, 12A is thicker as shown in FIG. 5 in the embodiment. Accordingly, solder crack around the bend portions 11A, 12A is hardly generated when tensile stress is applied to a solder junction portion.

FIG. 7 is an exemplary table showing TFT test data according to the embodiment compared to the comparative example as shown in FIG. 3. Here, a TFT condition is set to be 25-115° C. (ΔTc=90° C.). A total number of defects are expressed in the table to a number of a TFT cycle. The defects are an electrical characteristic defects due to solder crack.

In a case of a comparative example having one electrode terminal in a solder junction portion, a defect is generated on 30×10³ of a number of a TFT cycle at a temperature of 30 K.

On the other hand, in a case of this embodiment where the terminals 11, 12 are soldered with the solder 24 on the electrode 23, a defect is not generated till 60×10³ of a number of a TFT cycle.

In such a manner, reliability respect to thermal stress in this embodiment is remarkably improved as compared to the comparative example.

Further, two terminals 11, 12 are connected to the electrode 23 in this embodiment. Accordingly, wiring resistance is decreased by half as compared to the case of connecting one electrode terminal, so that this embodiment also improves electric characteristics.

Next, an electrode has a plural pairs of terminals mentioned above are illustrated by an example.

A power module can mount a plural pairs of a same kind of semiconductor chips. In such a case, a plural pairs of electrodes shared by the semiconductor chips pairs are established and an electrode terminal can be connected to the plural pairs of electrodes.

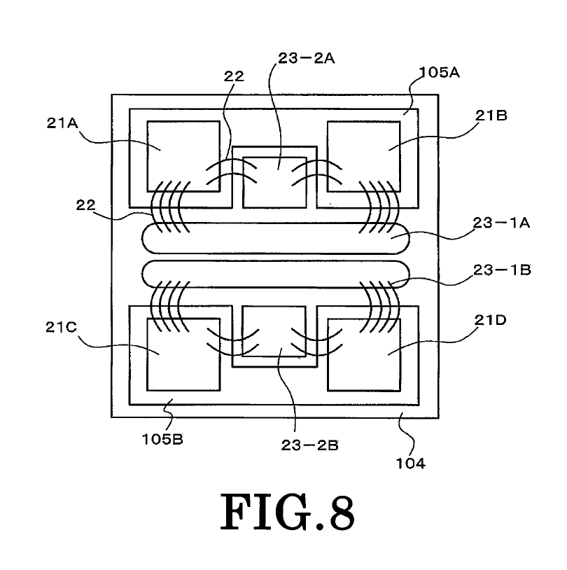

FIG. 8 shows a constitution of a semiconductor device in which four semiconductor chips 21A-21D are established as an example. FIG. 8 is a schematic plane view of the constitution of the semiconductor device.

The semiconductor chips 21A, 21B connected to an upper electrode 105A shares electrodes 23-1A and 23-2A by bonding wires 22. As the same as above feature, the semiconductor chips 21C, 21D connected to an upper electrode 105B shares electrodes 23-1B and 23-2B by the bonding wires 22.

In the figure, the electrodes 23-1A, 23-1B are connected to one electrode terminal and the electrodes 23-2A, 23-2B are connected to another electrode terminal.

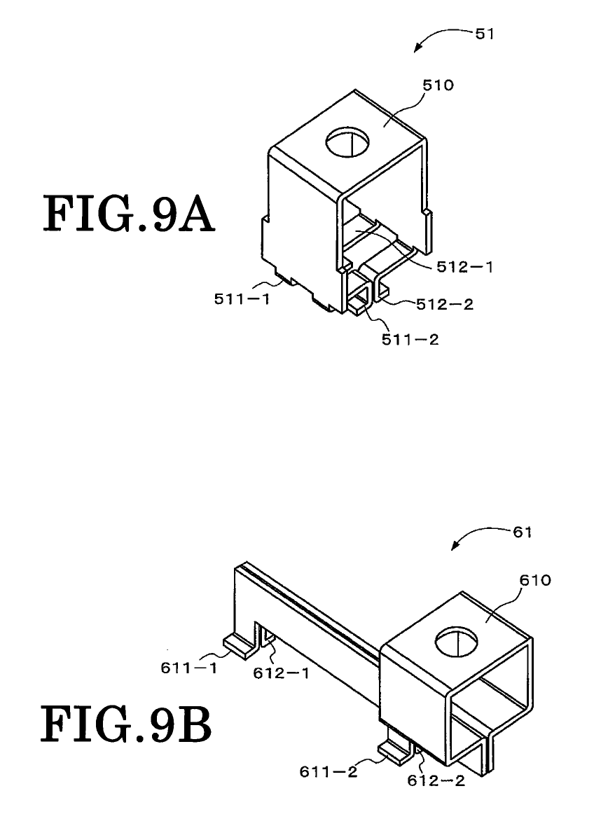

FIG. 9A, is an exemplary schematic view showing an electrode terminal 51 connected to the electrodes 23-1A, 23-1B.

An electrode terminal 51 includes a plane portion 510 formed as a planer board and a plurality of terminals 511-1, 511-2, 512-1 and 512-2. Both end portions of the plane portion 510 are bended in nearly orthogonal direction to lead to the terminals 511-1, 511-2, 512-1 and 512-2 which are bended back to be directed to a center portion of the electrode terminal 51, such that the terminals 511-1 and 511-2 are opposed to terminals 512-1, 512-2, respectively. Further, both bend portions of the terminal 511-1, 512-1 and bend portions of the terminals 511-2, 512-2, which are bended to lead to surfaces to be soldered, respectively, are formed back to back each other. Finally, both leading edges of the bend portions of the terminal 511-1, 512-1 and leading edges of the bend portions of the terminals 511-2, 512-2 are set to be outward-directed each other, respectively.

The terminals 511-1, 512-1 are soldered with the electrode 23-1A and the terminals 511-2, 512-2 are soldered with the electrode 23-1B.

In this shape, intervals in a small scale are set between both the bend portions of the terminals 511-1, 512-1 and the bend portions of the terminals 511-2, 512-2.

FIG. 9B is an exemplary schematic view showing an electrode terminal 61 connected to the electrodes 105A, 105B as shown in FIG. 8.

An electrode terminal 61 includes a plane portion 610 formed as a planer board and a plurality of terminals 611-1, 611-2, 612-1 and 612-2. Both end portions of the plane portion 610 are bended in nearly orthogonal direction to lead to the terminals 611-1, 611-2, 612-1 and 612-2 which are bended back to be directed to a center portion of the electrode terminal 61, such that the terminals 611-1 and 611-2 are opposed to terminals 612-1, 612-2, respectively. Further, both bend portions of the terminal 611-1, 612-1 and bend portions of the terminals 611-2, 612-2, which are bended to lead to surfaces to be soldered, respectively, are formed back to back each other. Finally, both leading edges of the bend portions of the terminal 611-1, 612-1 and leading edges of the bend portions of the terminals 611-2, 612-2 are set to be outward-directed each other, respectively.

The terminals 611-1, 612-1 are soldered with the electrode 105A and the terminals 611-2, 612-2 are soldered with the electrode 105B.

In this shape, intervals in a small scale are set between both the bend portions of the terminals 611-1, 612-1 and the bend portions of the terminals 611-2, 612-2.

As shown in FIGS. 9A, 9B, reliability respect to thermal stress generated in solder junction portion of each electrode can be improved due to setting each electrode terminal at a portion of solder connection portion of each of electrodes.

As described in the embodiment of the semiconductor device and the electrode terminal mentioned above, reliability respect to thermal stress generated in solder junction portion of the terminal electrode can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a substrate;
a semiconductor chip mounted on the substrate;
an electrode electrically connected to the semiconductor chip;
an electrode terminal having a first terminal at one end portion and a second terminal at the other end portion; and
a case covering the substrate, the electrode, the first terminal and the second terminal; wherein
the first terminal and the second terminal are bended to direct to a center portion and to be opposed each other in the case, and the first terminal and the second terminal are close to each other to be soldered with the electrode.

2. The semiconductor device of claim 1, wherein
the electrode terminal has a plurality of pairs of the first terminal and the second terminal.

3. The semiconductor device of claim 1, wherein
bend portions of the first terminal and the second terminal are back to back each other and are lead to surfaces to be soldered, and each of leading edge portions of the bend portions of the first terminal and the second terminal is set to be outward-directed.

4. The semiconductor device of claim 3, wherein
the electrode terminal has a plurality of pairs of the first terminal and the second terminal.

5. The semiconductor device of claim 3, further comprising:
an interval provided between the bend portions of the first terminal and the second terminal.

6. The semiconductor device of claim 5, wherein
the electrode terminal has a plurality of pairs of the first terminal and the second terminal.

7. The semiconductor device of claim 5, further comprising:
a solder provided in the interval.

8. The semiconductor device of claim 5, wherein
the interval has a width of nearly 1 mm.

9. The semiconductor device of claim 1, wherein
a portion of the electrode terminal exposed outside the case is constituted as a planar board.

10. The semiconductor device of claim 1, wherein
the semiconductor chip includes an insulated gate bipolar transistor, and the electrode terminal is a collector terminal or an emitter terminal of the insulated gate bipolar transistor.

11. The semiconductor device of claim 1, wherein
the semiconductor chip is electrically connected to the electrode by a bonding wire.

12. The semiconductor device of claim 1, wherein
a metal base is soldered on a surface of the semiconductor chip opposed to a side of the substrate on which the semiconductor chip is mounted.

13. The semiconductor device of claim 11, wherein
The substrate and the metal base are composed of AlN and copper, respectively.

14. An electrode terminal, comprising:
a plane portion formed as a planer board; and
a first terminal portion and a second terminal portion being bended in nearly orthogonal direction from both edges of the plane portion and further being bended back to be directed to a center portion of the electrode terminal such that the first terminal portion and the second terminal portion being opposed to each other, bend portions of the first terminal portion and the second terminal portion being back to back each other and further being bended to lead to surfaces to be soldered with the electrode, each of leading edges of the bend portions being set to be outward-directed.

15. The electrode terminal of claim 14, further comprising:
an interval provided between the bend portions of the first terminal and the second terminal.

16. The electrode terminal of claim 15, further comprising:
a solder provided in the interval.

17. The electrode terminal of claim 15, wherein
the interval has a width of nearly 1 mm.

18. The electrode terminal of claim 14, wherein
the electrode terminal has a plurality of pairs of the first terminal and the second terminal.

19. The electrode terminal of claim 16, wherein
the electrode terminal has a plurality of pairs of the first terminal and the second terminal.
